(19) United States
(12) Patent Application Publication
(10) Pub. No.: US 2024/0047384 A1
(43) Pub. Date: Feb. 8, 2024

(54) METHOD OF MANUFACTURING A SEMICONDUCTOR DEVICE AND A SEMICONDUCTOR DEVICE

(71) Applicant: TAIWAN SEMICONDUCTOR MANUFACTURING COMPANY, LTD., Hsinchu (TW)

(72) Inventors: Chi-Hui LAI, Taichung City (TW); Yang-Che CHEN, Hsinchu City (TW); Hsiang-Tai LU, Zhubei City (TW); Wei-Ray LIN, Hsinchu City (TW)

(21) Appl. No.: 18/109,116

(22) Filed: Feb. 13, 2023

Related U.S. Application Data
(60) Provisional application No. 63/396,048, filed on Aug. 8, 2022.

(51) Int. Cl. H01L 23/58; H01L 23/528; H01L 21/78

(52) U.S. Cl. CPC H01L 23/585; H01L 23/528; H01L 21/78

(57) ABSTRACT

A semiconductor device includes a first circuit area disposed over a substrate and enclosed by a first seal ring structure, a second circuit area disposed over the substrate and enclosed by a second seal ring structure, an internal scribe line disposed between the first circuit area and the second circuit area, and connecting seal structures connecting the first seal ring structure and the second seal ring structures such that a part of the first seal ring structure, a part of the second seal ring structure and the connecting seal structures enclose the internal scribe line.

### RELATED APPLICATIONS

This application claims priority of U.S. Provisional Patent Application No. 63/396,048 filed Aug. 8, 2022, the entire content of which is incorporate herein by reference.

### BACKGROUND

In developing a semiconductor device, such as an integrated circuit (IC) or a large scale integration (LSI), various circuit designs (layouts) are tested before obtaining a final circuit design. Since the cost of a manufacturing operation of the semiconductor device, in particular the lithography cost, has increased rapidly, reducing the cost for manufacturing test photo masks has been required. In addition, as the dimensions of the semiconductor devices decrease, a more flexible design of the circuit layout is required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A shows a plan or layout view (viewed from the above) illustrating a lower seal ring structure of a semiconductor device according to an embodiment of the present disclosure.

FIG. 1B shows an enlarged view of the circled portion of FIG. 1A, FIG. 1C shows a cross sectional view along line X1-X1 of FIG. 1A, and FIG. 1D shows a cross sectional view along line X2-X2 of FIG. 1A.

FIG. 2A shows a plan or layout view (viewed from the above) illustrating upper and lower seal ring structures of a semiconductor device according to an embodiment of the present disclosure. FIG. 2B shows an enlarged view of the circled portion of FIG. 2A, FIG. 2C shows a cross sectional view along line X1-X1 of FIG. 2A, and FIG. 2D shows a cross sectional view along line X2-X2 of FIG. 2A.

FIG. 3A shows a plan or layout view (viewed from the above) illustrating upper and lower seal ring structures of a semiconductor device according to an embodiment of the present disclosure. FIG. 3B shows an enlarged view of the circled portion of FIG. 3A, FIG. 3C shows a cross sectional view along line X1-X1 of FIG. 3A, FIG. 3D shows a cross sectional view along line X2-X2 of FIG. 3A and FIG. 3E shows a cross sectional view along line Y1-Y1 of FIG. 3A.

FIG. 3F shows a plan or layout view illustrating upper and lower seal ring structure of a semiconductor device according to an embodiment of the present disclosure.

FIG. 4A shows a cross sectional view along line Y1-Y1 of FIG. 2A and FIG. 4B shows a cross sectional view along line Y1-Y1 of FIG. 3A according to embodiments of the present disclosure.

FIG. 5 illustrates a plan view of the seal ring structure in accordance with embodiments of the present disclosure.

FIG. 6 shows a wafer layout of semiconductor devices according to the present disclosure.

FIG. 7A shows a wafer layout of semiconductor devices according to the present disclosure. FIGS. 7B and 7C show views of the semiconductor devices after dicing according to embodiments of the present disclosure.

FIGS. 8A, 8B, 8C, 8D, 8E and 8F show plan views of various seal ring structures according to embodiments of the present disclosure.

FIGS. 9A, 9B, 9C and 9D show plan views of various seal ring structures according to embodiments of the present disclosure.

FIG. 10 is a flow chart of a sequential manufacturing operation of a semiconductor device according to embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

During development of a new semiconductor device (circuit), various candidate or test circuit patterns are designed and tested before obtaining a final circuit pattern. In some cases, the test patterns include a first circuit pattern (a first project) and a second circuit pattern (a second project), which can individually function as a semiconductor device and can function as one integrated semiconductor device. In the developing stage, either of the first or second circuits or the combination of the first and second circuits may be used and manufactured accordingly. In addition, two or more circuits are used individually or in combination thereof depending on customers' need.

However, the cost of manufacturing the semiconductor device increases and a turn-around-time (TAT) of the manufacturing the semiconductor device also increase. In particular, the state-of-the-art semiconductor manufacturing requires an extreme ultraviolet (EUV) lithography and/or an immersion DUV lithography, of which the cost is very high. Specifically, photomasks used in the EUV lithography are very expensive. Accordingly, it is required to reduce number of photomasks during the device development stage.

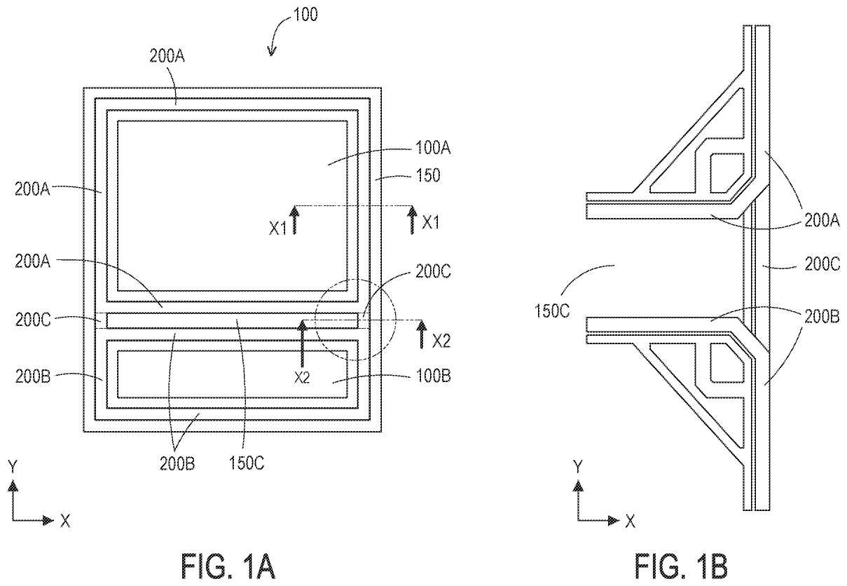

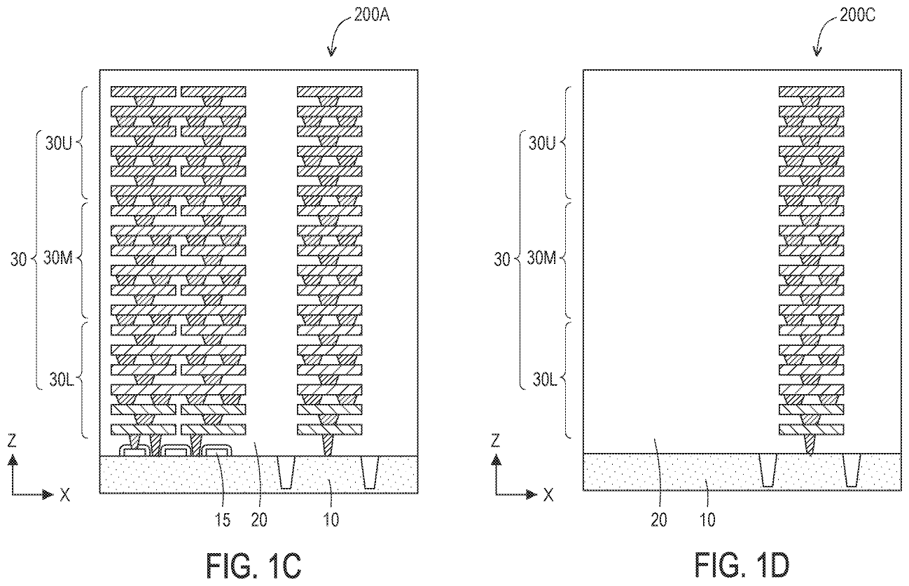

FIG. 1A shows a plan or layout view (viewed from the above) illustrating a lower seal ring structure of a semiconductor device according to an embodiment of the present disclosure. FIG. 1B shows an enlarged view of the circled portion of FIG. 1A, FIG. 1C shows a cross sectional view along line X1-X1 of FIG. 1A, and FIG. 1D shows a cross sectional view along line X2-X2 of FIG. 1A.

In some embodiments, a semiconductor device 100 includes a first circuit 100A and a second circuit 100B as shown in FIG. 1A. In some embodiments, the first circuit 100A and the second circuit 100B function as a semiconductor device independently from each other, and also function as one integrated semiconductor device together by electrically connecting the first and second circuits with one or more wiring patterns. The first circuit 100A and the second circuit 100B are separated by an internal scribe line 150C. In some embodiments, the area of the first circuit 100A is the same as or different from the area of the second circuit 100B.

In some embodiments, the first circuit 100A is surrounded by a first lower seal ring structure 200A, and the second circuit 100B is surrounded by a second lower seal ring structure 200B as shown in FIG. 1A. In addition, the first lower seal ring structure 200A and the second lower seal ring structure 200B are connected by connecting seal ring structures 200C such that three sides of the first lower seal ring structure 200A (other than the side facing the internal scribe line 150C), three sides of the second lower seal ring structure 200B (other than the side facing the internal scribe line 150C) and the connecting seal ring structures 200C surround the first and second circuits. The seal ring structure is an electric, physical and/or chemical guard ring to suppress or avoid noise, stress caused by a dicing or sawing process and/or contamination.

In some embodiments, the first circuit 100A and the second circuit 100B include transistors 15 (e.g., planer field effect transistors (FETs), fin FETs, gate-all-around FETs, etc.) formed over a semiconductor substrate 10 as shown in FIG. 1C. In some embodiments, the FETs 15 include a gate, a source and a drain. In the present disclosure, a source and a drain are interchangeably used and may have the same structure. In some embodiments, one or more interlayer dielectric (ILD) layers 20 are formed over the FETs 15.

In some embodiments, the substrate 10 may be made of a suitable elemental semiconductor, such as silicon, diamond or germanium; a suitable alloy or compound semiconductor, such as Group-IV compound semiconductors (e.g., silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide (InGaAs), indium arsenide, indium phosphide, indium antimonide, gallium arsenic phosphide, or gallium indium phosphide), or the like. The substrate 10 includes isolation regions in some embodiments, such as a shallow trench isolation (STI), located between active regions and separating one or more electronic elements from other electronic elements.

Further, the first and second circuits include multiple wiring layers 30 (x-th wiring layer) formed over the FETs, where x is 1, 2, 3, . . . , as shown in FIG. 1C. Each of the wiring layers includes conductive wiring pattern and via contacts connected above the wiring patterns, and each of the next (upper) wiring layers ((x+1)-th wiring layer) includes conductive wiring pattern and via contacts connected above the wiring patterns. Similarly, the lower wiring layers includes conductive wiring pattern and via contacts connected above the wiring patterns. In some embodiments, when the wiring layers include wiring patterns extending in the X direction, the next wiring layers include wiring patterns extending in the Y direction. In other words, X-direction metal wiring patterns and Y-direction metal wiring patterns are alternately stacked in the vertical direction. In some embodiments, x is up to 20. In some embodiments, the lowest wiring layer can include the wiring patterns closest to the FETs 15 except for local interconnects. Each of the wiring layers also includes one or more ILD layers or inter-metal dielectric (IMD) layers. In other embodiments, the wiring layer can include via contacts formed above the metal wiring patterns.

In some embodiments, the multiple wiring layers 30 includes lower wiring layers 30L, middle wiring layers 30M and upper wiring layers 30U as shown in FIG. 1C. Each of the lower, middle and upper wiring layers includes two to ten wiring layers in some embodiments. In some embodiments, the lower wiring layers 30L include fine patterns that require EUV lithography to be formed. The pattern sizes or dimensions of the middle wiring layers 30M are greater than those of the lower wiring layers 30L, and the pattern sizes or dimensions of the upper wiring layers 30U are greater than those of the middle wiring layers 30M. In some embodiments, the middle wiring layers 30M and/or the upper wiring layers 30U include patterns that do not require EUV lithography to be formed. In some embodiments, no middle wiring layers are included.

As shown in FIGS. 1C and 1D, the seal ring structures 200A, 200B and 200C have the similar wiring structures 30.

The seal ring structure includes contacts/vias and metal wiring patterns surrounding the circuit area of the chip. The contacts/vias and wiring patterns form one or more continuous ring or frame structure uninterrupted by any gaps to block any interference (e.g., noise, ions, stress, etc.) from outside. In some embodiments, the seal ring structures are not connected to any transistors, or no transistor is disposed below the seal ring structures. In some embodiments, the seal ring structures are coupled to a fixed potential (e.g., the ground) through a diffusion region in the substrate and/or a top (pad) electrode. Outside the seal ring structure are scribe line areas.

As shown in FIGS. 1C and 1D, each of the first lower seal ring structure 200A, the second lower seal ring structure 200B and the connecting seal ring structures 200C are composed of wiring patterns in a first to N-th wiring layers vertically arranged over the substrate and vias connecting vertically adjacent wiring patterns. In some embodiments, N is up to 20.

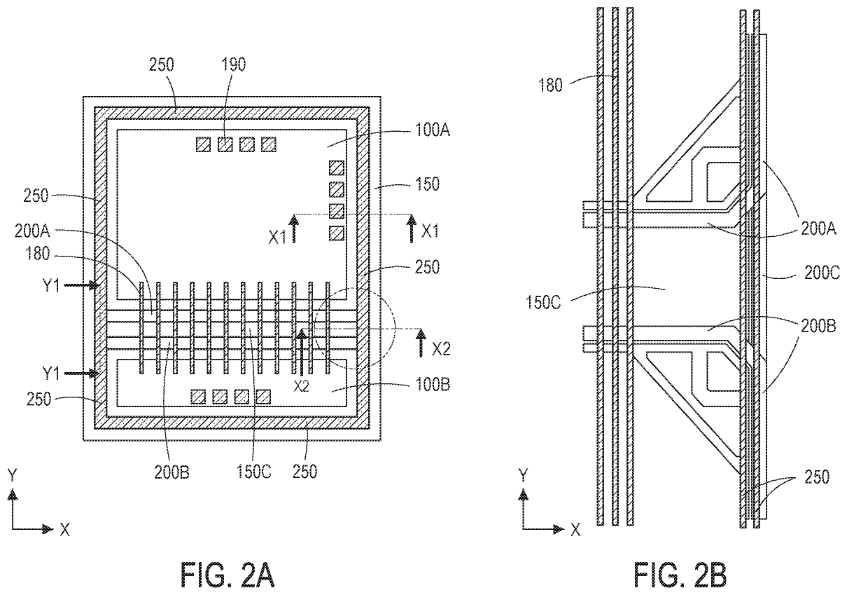

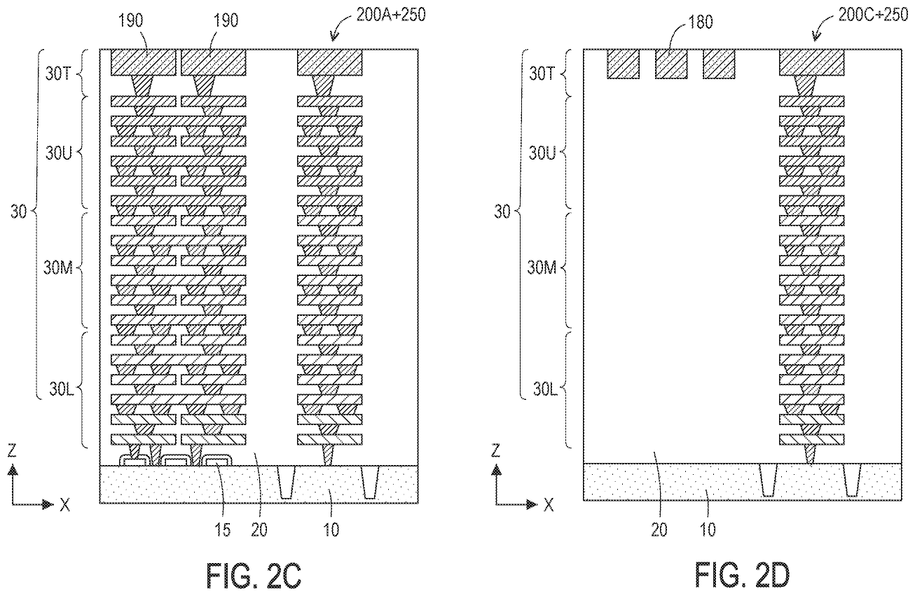

FIG. 2A shows a plan or layout view (viewed from the above) illustrating upper and lower seal ring structures of a semiconductor device according to an embodiment of the present disclosure. FIG. 2B shows an enlarged view of the circled portion of FIG. 2A, FIG. 2C shows a cross sectional view along line X1-X1 of FIG. 2A, and FIG. 2D shows a cross sectional view along line X2-X2 of FIG. 2A.

FIGS. 2A-2D show an embodiment in which the first circuit 100A and the second circuit 100B are combined as one semiconductor device (the first project). After the “common” structures shown in FIGS. 1A-1D are formed, an upper (a third) seal ring structure 250 is formed over the three sides of the first lower seal ring structure 200A, three sides of the second lower seal ring structure 200B and the connecting seal ring structures 200C to surround the first and second circuits, as shown in FIG. 2A. The upper seal ring structure 250 is connected to the first lower seal ring structure 200A and the second lower seal ring structure 200B by a plurality of vias as shown in FIGS. 2C and 2D. Accordingly, the combination of the upper seal ring structure and the three sides of the first lower seal ring structure 200A, three sides of the second lower seal ring structure 200B and the connecting seal ring structures 200C forms a complete seal ring structure surrounding the first and second circuits. The upper seal ring structure 250 is constituted by a top wiring layer 30T including the plurality of vias connected to the top layer (the N-th wiring pattern) of the lower seal ring structures and one or more conductive patterns (ring or frame patterns) as the uppermost conductive pattern. In some embodiments, the upper seal ring structure 250 is formed by one or more deposition, lithography and etching operations.

In some embodiments, circuit connection patterns 180 connecting the first circuit 100A and the second circuit 100B are formed bridging the internal scribe line 150C, as shown in FIGS. 2A and 2B. Further, in some embodiments, pad electrodes 190 are formed in at least one of the first circuit 100A or the second circuit 100B. The circuit connection patterns 180 and the pad electrodes 190 are constituted by the top wiring layer 30T including vias connected to the lower conductive patterns (the N-th wiring pattern) and conductive patterns as the uppermost conductive pattern. In some embodiments, the circuit connection patterns 180 and the pad electrodes 190 are formed together with the upper seal ring structure 250.

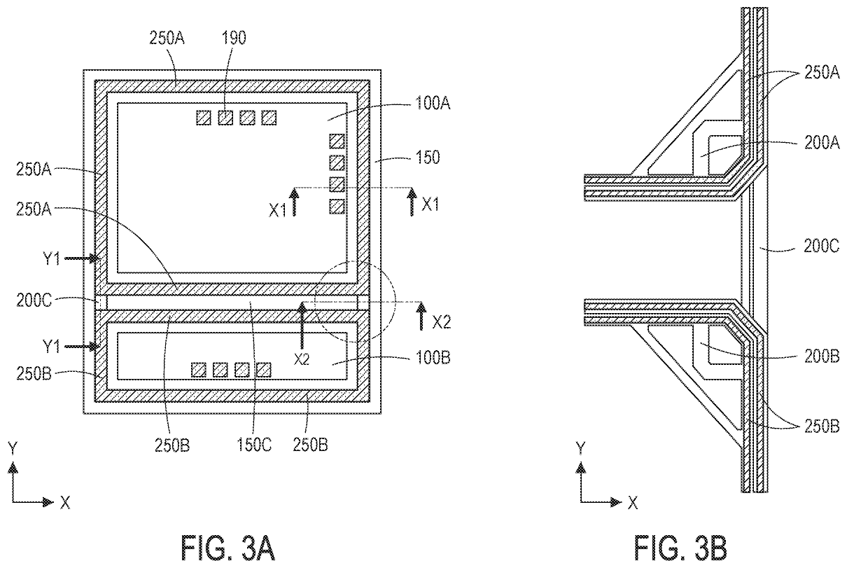

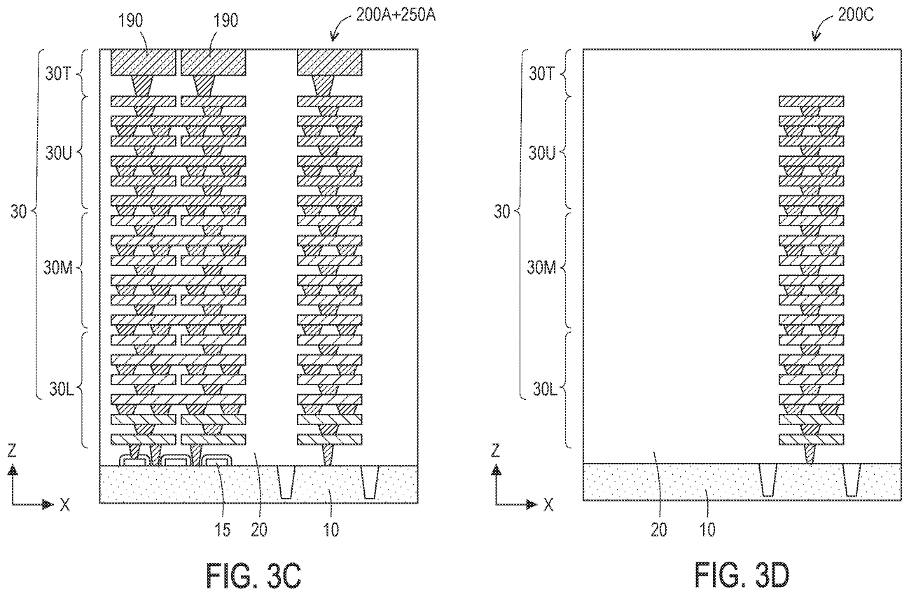

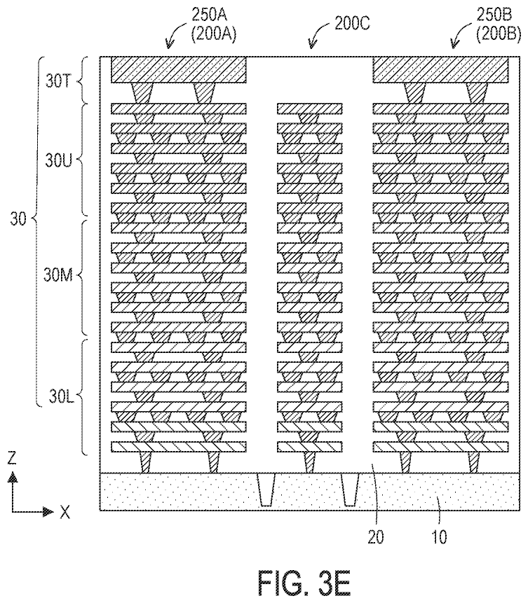

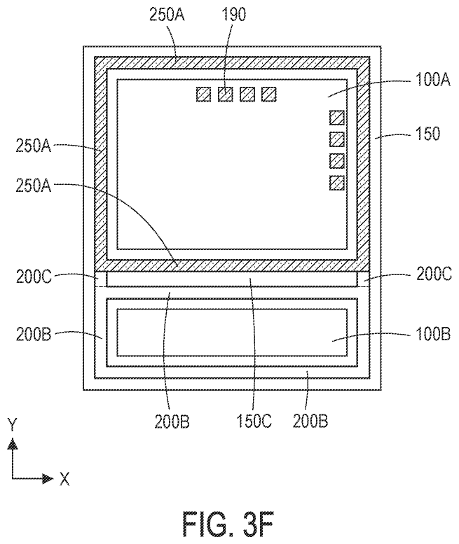

FIG. 3A shows a plan or layout view (viewed from the above) illustrating upper and the lower seal ring structures of a semiconductor device according to an embodiment of the present disclosure. FIG. 3B shows an enlarged view of the circled portion of FIG. 3A, FIG. 3C shows a cross sectional view along line X1-X1 of FIG. 3A, FIG. 3D shows a cross sectional view along line X2-X2 of FIG. 3A and FIG. 3E shows a cross sectional view along line Y1-Y1 of FIG. 3A.

FIGS. 3A-3E show an embodiment in which the first circuit 100A and the second circuit 100B are separately used (the second project). After the “common” structures shown in FIGS. 1A-1D are formed, a first upper seal ring structure 250A is formed over the first lower seal ring structure 200A and a second upper seal ring structure 250B is formed over the second lower seal ring structure 200B, as shown in FIG. 3A. No upper seal ring structure is formed over the connecting seal ring structures 200C in some embodiments, as shown in FIGS. 3A, 3D and 3E. In other embodiments, upper connecting seal ring structures are formed over the connecting seal ring structures 200C.

As shown in FIGS. 3A-3D, the combination of the first upper seal ring structure 250A and the first lower seal ring structure 200A forms a complete seal ring structure surrounding the first circuit 100A, and the combination of the second upper seal ring structure 250B and the second lower seal ring structure 200B forms a complete seal ring structure surrounding the second circuit 100B.

The first upper and second upper seal ring structures 250A, 250B are constituted by a top wiring layer 30T including a plurality of vias connected to the top layer (the N-th wiring pattern) of the lower seal ring structures and one or more conductive patterns (ring or frame patterns) as the uppermost conductive pattern. In some embodiments, the upper seal ring structures 250A and 250B are formed by one or more deposition, lithography and etching operations.

In some embodiments, pad electrodes 190 are formed in at least one of the first circuit 100A or the second circuit 100B. The pad electrodes 190 are constituted by the top wiring layer including vias connected to the lower conductive patterns (the N-th wiring pattern) and conductive patterns as the uppermost conductive pattern. In some embodiments, the pad electrodes 190 are formed together with the upper seal ring structures 250A and 250B.

In some embodiments, the lithography operations for the top wiring layer 30T do not require a higher resolution, and thus DUV or UV lithography operations can be employed. A transparent photomask for DUV or UV lithography is relatively low cost compared to a reflective photomask for EUV lithography. In the embodiments above, switching between the first project shown by FIGS. 2A-2D and the second project shown by FIG. 3A-3E requires two different photomask sets, each including two photomasks for forming vias and the uppermost wiring pattern. If totally different photomask sets are prepared for the first project and the second project (only chips of the first circuit are manufactured over a wafer or only chips of the second circuit are manufactured over a wafer), different ring structure patterns are required to be prepared for each wiring layer, which may require expensive EUV lithography. In contrast, in the embodiments above, it is possible to reduce the manufacturing cost for forming the test devices according to the first project or the second project compared to the case where totally different photomask sets are prepared for the first project and the second project.

In some embodiments, in the second project, only one of the first circuit 100A or the second circuit 100B is used. In such a case, as shown in FIG. 3F, only the first upper seal ring structure 250A is formed (if only the first circuit 100A is necessary) and no upper seal ring structure is formed to surround the second circuit 100B.

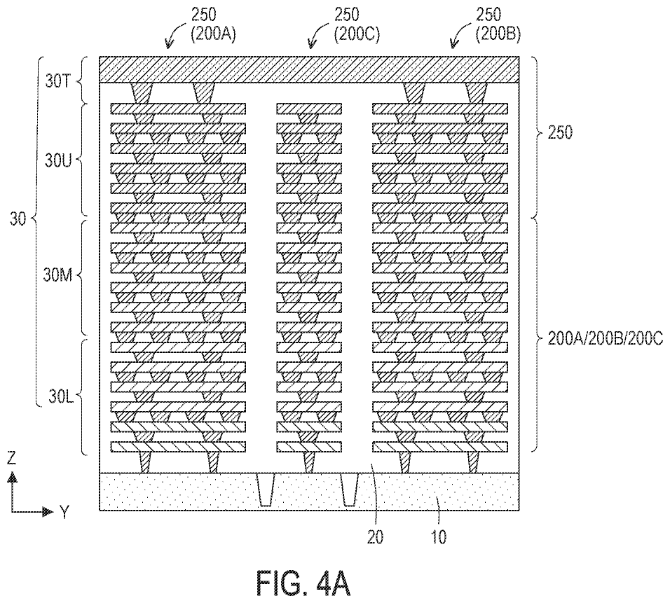

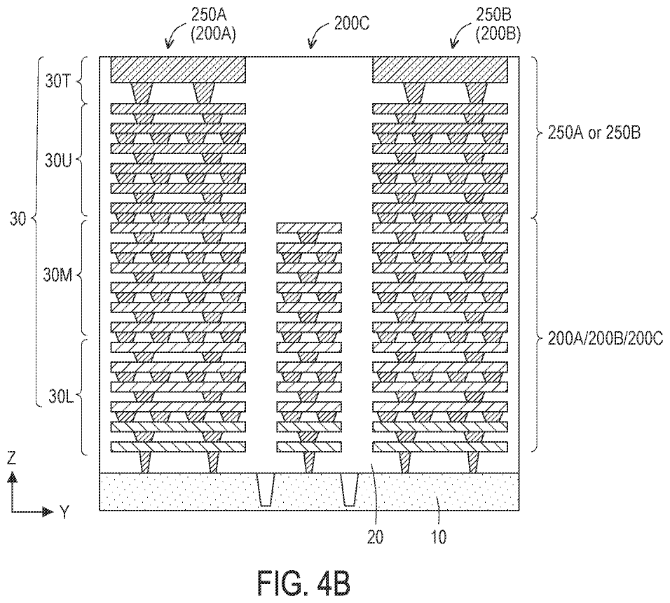

FIG. 4A shows a cross sectional view along line Y1-Y1 of FIG. 2A and FIG. 4B shows a cross sectional view along line Y1-Y1 of FIG. 3A according to embodiments of the present disclosure.

In the embodiments of FIGS. 2A-2D and 3A-3D as explained above, the wiring patterns (ring or frame pattern) of the upper seal ring structure 250, 250A and 250B are formed of the uppermost wiring pattern same as the pad electrodes 190. In other embodiments, the wiring patterns (ring or frame pattern) of the upper seal ring structure 250, 250A and 250B are formed of two or more wiring layers from the top (including the uppermost wiring patterns).

As shown in FIGS. 4A and 4B, each of the first lower seal ring structure 200A, the second lower seal ring structure 200B and the connecting seal structures 200C is composed of wiring patterns in the first to the (N−M)-th wiring layers vertically arranged and vias connecting vertically adjacent wiring patterns, and the upper seal ring structures 250, 250A and 250B are composed on wiring patterns in the (N−M+1)-th to the N-th wiring layers vertically arranged and vias connecting vertically adjacent wiring patterns, where M<N (N, M are natural number more than two). In some embodiments, M is up to 10, for example, 1, 2, 3, 4, or 5.

In some embodiments, each of the first lower seal ring structure 200A, the second lower seal ring structure 200B and the connecting seal structures 200C is composed of the upper wiring layers 30U and the top wiring layer 30T as shown in FIGS. 4A and 4B. In some embodiments, the upper wiring layers 30U include patterns that do not require EUV lithography to be formed and can be formed by DUV (using KrF or ArF excimer laser) lithography or even UV lithography (e.g.—i-line lithography).

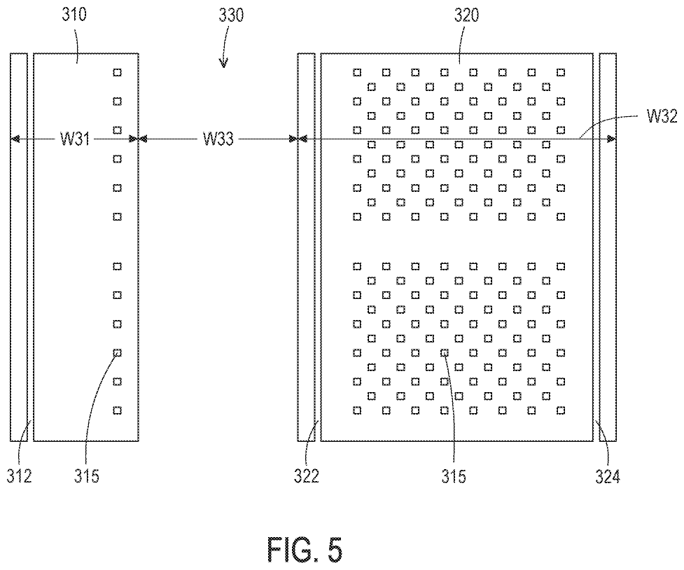

FIG. 5 shows a plan view of one of the wiring patterns of the seal ring structures according to some embodiments of the present disclosure.

As set forth above, the seal ring structures include a stack of wiring layers (wiring patterns) and vias connecting vertically adjacent wiring layers. In some embodiments, the wiring pattern of each of the lower seal ring structures and the upper seal ring structures includes a first line pattern 310 (frame or ring shape) and a second line pattern 320 (frame or ring shape) spaced apart from each other by a gap 330.

In some embodiments, a plurality of vias 315 are provided over/under the first line pattern 310 and the second line pattern 320, respectively. The plurality of vias are filled with a conductive material and connected to the lower wiring pattern. In some embodiments, the plurality of vias are arranged in a matrix, for example a staggered matrix.

In some embodiments, one or more slits 312, 322 and 324 are optionally provided to the first line pattern 310 and the second line pattern 320. In some embodiments, the slits are filled with a conductive material and connected to the lower wiring pattern.

In some embodiments, the width W31 of the first line pattern is in a range from about 0.5 μm to about 5 μm. In some embodiments, the width W32 of the second line pattern is greater than the width W31 and is in a range from about 2 μm to about 15 μm. In some embodiments, the space W33 between the first and second line patterns is in a range from about 2 μm to about 20 μm. In some embodiments, a size of the vias is in a range from about 100 nm to about 1000 nm. In some embodiments, a width of the slit is in a range from about 200 nm to about 500 nm. In some embodiments, one or more of the widths/spaces W31, W32 or W33 are different between the first and second inner seal ring structures, between the inner seal ring structures and the field barrier structures and/or between the field barrier structures.

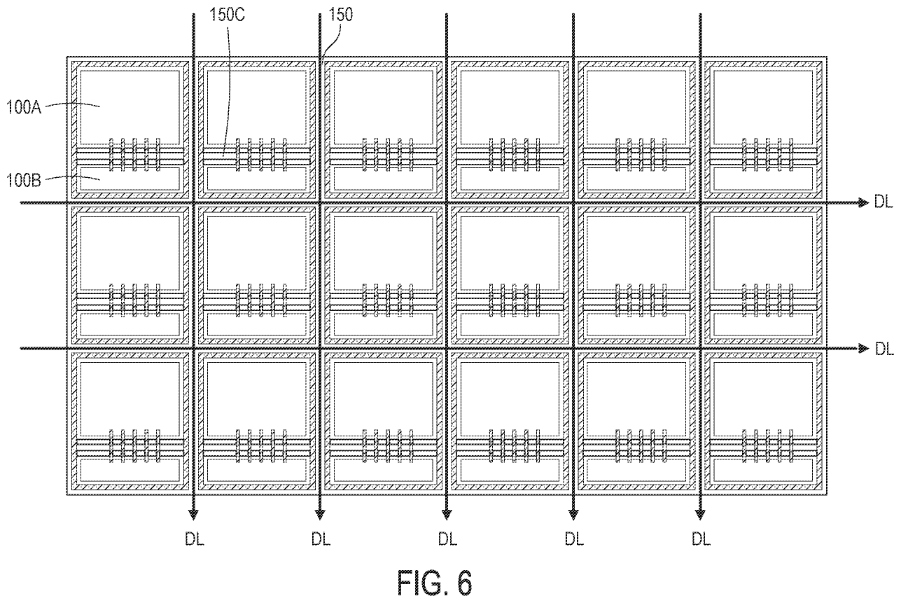

FIG. 6 shows a wafer chip layout of semiconductor devices for the first project as explained with respect to FIGS. 1 and 2A-2D according to the present disclosure.

As explained above, in the first project, the combination of the first circuit 100A and the second circuit 100B connecting connection patterns 180 is treated as one chip (semiconductor device). Accordingly, the dicing operation DL cuts out the chips from the wafer such that the dicing operations cut the scribe line 150 surrounding the first circuit 100A and the second circuit 100B as a whole, and does not cut the inner scribe line 150C, as shown in FIG. 6.

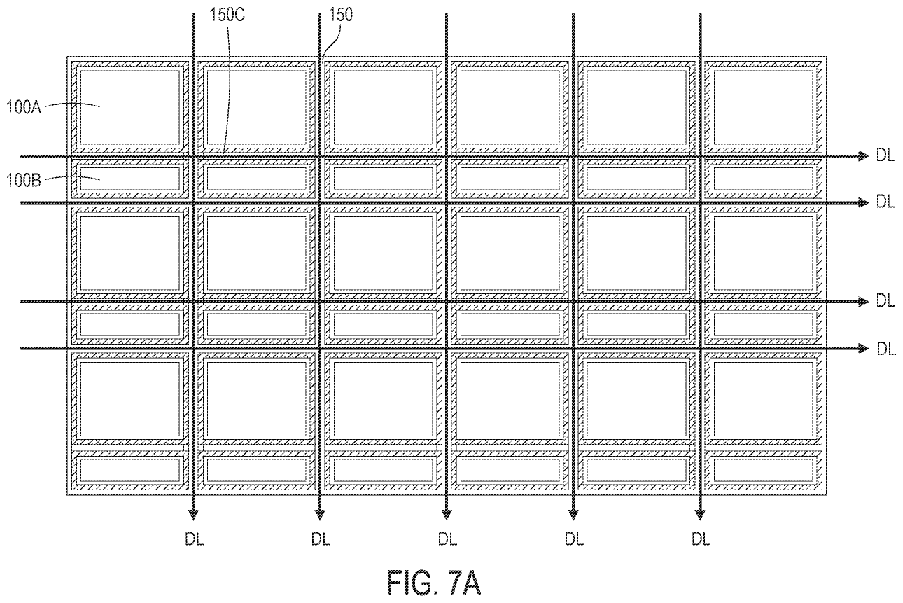

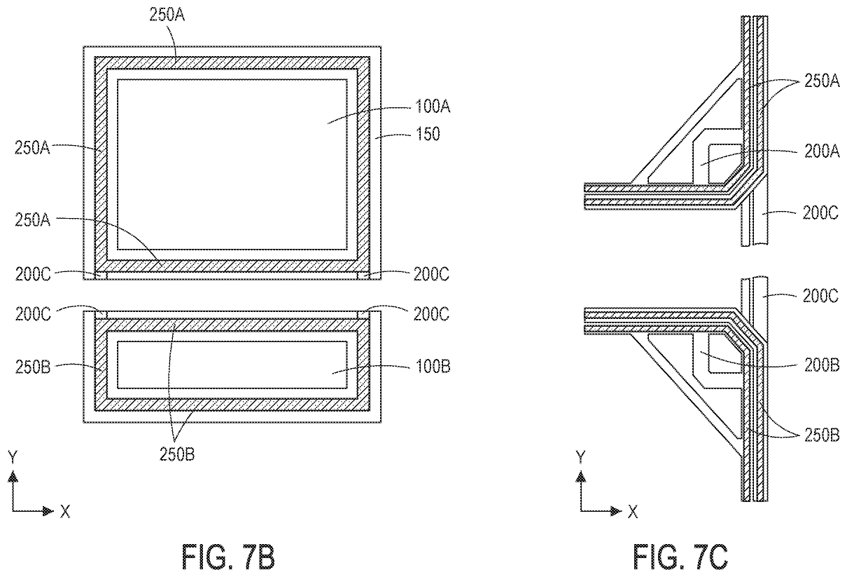

FIG. 7A shows a part of a wafer chip layout of semiconductor devices for the second project as explained with respect to FIGS. 1 and 3A-3E according to the present disclosure.

In the second project, the first circuit 100A and the second circuit 100B are treated as separate functional chips (semiconductor devices), respectively. Accordingly, the dicing operation DL cuts out the chips from the wafer such that the dicing operations cut the scribe line 150 surrounding the first circuit 100A and the second circuit 100B and cut the inner scribe line 150C, as shown in FIG. 7A

FIGS. 7B and 7C show views of the semiconductor devices after dicing according to embodiments of the present disclosure.

As shown in FIGS. 7B and 7C, since the connecting seal ring structure 200C (lower seal ring structure) is cut in the dicing operation, the lower seal ring structure includes two lateral protrusions laterally protruding beyond the upper seal ring structures 250A or 250B in plan view. Accordingly, the cut wiring patterns are exposed at the end face of the diced edges of the chip of the first circuit and the chip of the second circuit.

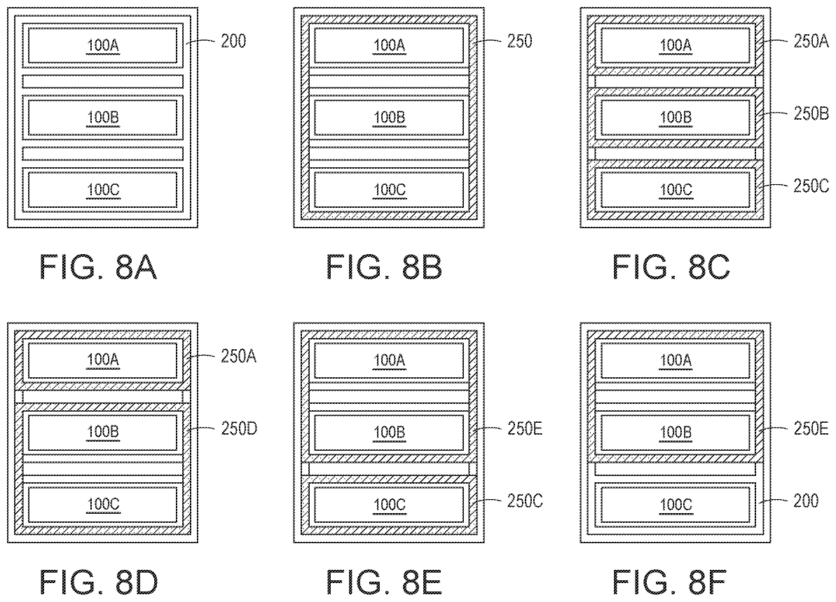

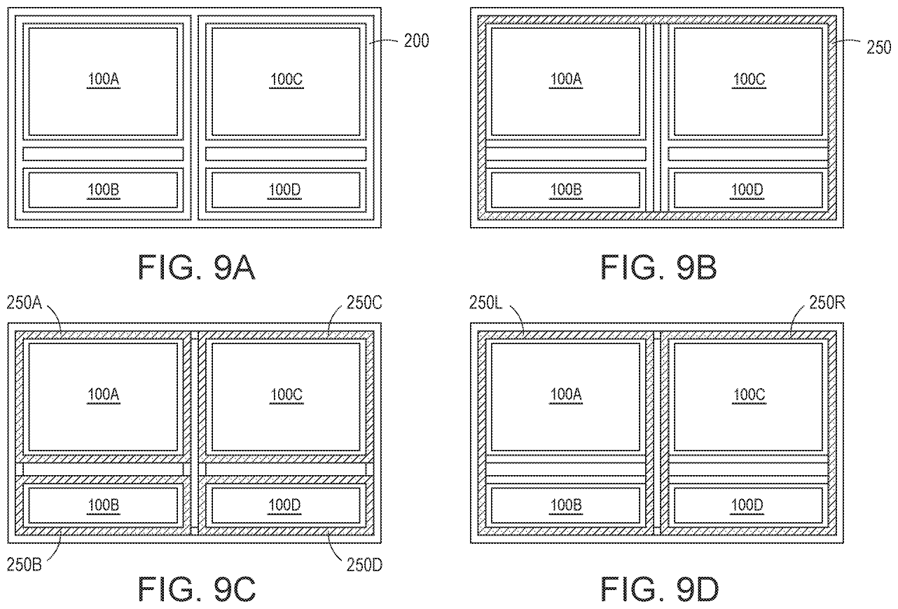

FIGS. 8A-8F and FIGS. 9A-9D show plan views of various seal ring structures according to embodiments of the present disclosure.

In the foregoing embodiments, two circuits, the first circuit 100A and the second circuit 100B are selectively used or combined. However, the number of circuits is not limited to two.

In some embodiments, the number of circuits is three as shown in FIGS. 8A-8F. FIG. 8A shows a structure of the first circuit 100A, the second circuit 100, the third circuit 100C as well as lower seal ring structures 200 common to FIGS. 8B-BF. In the first project, the three circuits 100A, 100B and 100C are combined as one chip and the one upper seal ring structure 250 is formed to surround the three circuits 100A, 100B and 100C, as shown in FIG. 8B in some embodiments. In the second project, each of the first, second and third circuits 100A, 100B and 100C is individually used and the first upper seal ring structure 250A, the second upper seal ring structure 250B and the third upper seal ring structure 250C are formed to surround the first, second and third circuits 100A, 100B and 100C, respectively, as shown in FIG. 8C in some embodiments. In the third project, the first circuit 100A is independently used, and the combination of the second and third circuits 100B and 100C is used as one semiconductor device. In such a case, the first upper seal ring structure 250A is formed to surround the first circuit and an upper common seal ring structure 250D is formed to surround the second and third circuits 100B and 100C, as shown in FIG. 8D. In the fourth project, the third circuit 100C is independently used, and the combination of the first and second circuits 100A and 100B is used as one semiconductor device. In such a case, the third upper seal ring structure 250C is formed to surround the third circuit and an upper common seal ring structure 250E is formed to surround the first and second circuits 100A and 100B, as shown in FIG. 8E. In some embodiments, one or two of the first to third circuits are not necessary. In such a case, no upper seal ring structure is formed over such a circuit(s), as shown in FIG. 8F.

In some embodiments, the number of circuits is four, as shown in FIGS. 9A-9D. FIG. 9A shows a structure of the first circuit 100A, the second circuit 100, the third circuit 100C and the fourth circuit 100D as well as lower seal ring structures 200 that is common to FIGS. 9B-9D. In the first project, the four circuits 100A, 100B, 100C and 100D are combined as one chip and the one upper seal ring structure 250 is formed to surround the four circuits 100A, 100B, 100C and 100D, as shown in FIG. 9B in some embodiments.

In the second project, each of the first, second, third and fourth circuits 100A, 100B, 100C and 100D is individually used and the first upper seal ring structure 250A, the second upper seal ring structure 250B, the third upper seal ring structure 250C and the fourth upper seal ring structure 250D are formed to surround the first, second, third and fourth circuits 100A, 100B, 100C and 100D, respectively, as shown in FIG. 9C in some embodiments. In the third project, the first circuit 100A and the second circuit 100B are combined, and the combination of the third and fourth circuits 100C and 100D is used as one semiconductor device. In such a case, the first common upper seal ring structure 250L is formed to surround the first circuit 100A and the second circuit 100B, and the second common upper seal ring structure 250R is formed to surround the third and fourth circuits 100C and 100D, as shown in FIG. 9D.

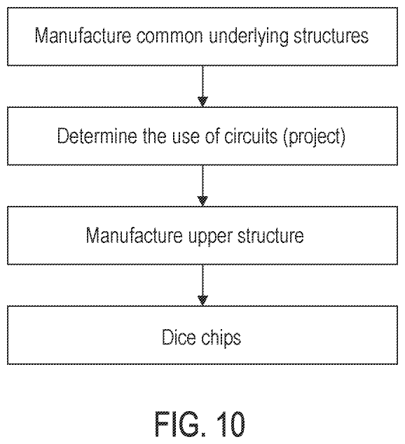

FIG. 10 is a flow chart of a sequential manufacturing operation of a semiconductor device. It is understood that additional operations can be provided before, during, and after processes shown in FIG. 10, and some of the operations described below can be replaced or eliminated, for additional embodiments of the method. The order of the operations/processes may be interchangeable. Further, materials, configurations, dimensions and/or processes as explained with respect to the foregoing embodiments may be employed in the following embodiment, and the detailed explanation may be omitted.

In some embodiments, a semiconductor wafer including a plurality of chip areas is prepared. Each of the plurality of chip areas includes a first circuit area enclosed by a first lower seal ring structure, a second circuit area enclosed by a second lower seal ring structure, an internal scribe line disposed between the first circuit area and the second circuit area, and connecting seal structures connecting the first seal ring structure and the second seal ring structures such that a part of the first seal ring structure, a part of the second seal ring structure and the connecting seal structures enclose the internal scribe line. Then, the project is determined between the first project in which the combination of the first circuit and the second circuit is used as one semiconductor device or the second project in which the first circuit and the second circuit are individually used as different semiconductor devices. In some embodiments, the second project includes using only one of the first circuit or the second circuit as a semiconductor device. Then, according to the selected project, photo masks for forming the upper layers including an upper seal ring structures are manufactured, and the upper (third) seal ring structure(s) is/are formed. Then, the dicing operation is performed to cut our semiconductor chips. When the second project is selected, the dicing operation includes dicing the internal scribe line.

It will be understood that not all advantages have been necessarily discussed herein, no particular advantage is required for all embodiments or examples, and other embodiments or examples may offer different advantages.

According to one aspect of the present disclosure, a semiconductor device includes a first circuit area disposed over a substrate and enclosed by a first seal ring structure, a second circuit area disposed over the substrate and enclosed by a second seal ring structure, an internal scribe line disposed between the first circuit area and the second circuit area, and connecting seal structures connecting the first seal ring structure and the second seal ring structures such that a part of the first seal ring structure, a part of the second seal ring structure and the connecting seal structures enclose the internal scribe line. In one or more of the foregoing and following embodiments, the semiconductor device further includes a third seal ring structure enclosing the first circuit area and the second circuit area. In one or more of the foregoing and following embodiments, each of the first seal ring structure, the second seal ring structure and the connecting seal structure is composed of wiring patterns in a first to (N−M)-th wiring layers vertically arranged and vias connecting vertically adjacent wiring patterns, and the third seal ring structure is composed on wiring patterns in a (N−M+1)-th to an N-th wiring layers vertically arranged and vias connecting vertically adjacent wiring patterns, where M<N. In one or more of the foregoing and following embodiments, the semiconductor device further includes a pad electrode composed of a wiring pattern in the N-th wiring layer. In one or more of the foregoing and following embodiments, the N-th wiring layer is an uppermost wiring layer of the semiconductor device. In one or more of the foregoing and following embodiments, M is 2 or 3. In one or more of the foregoing and following embodiments, each of the first seal ring structure, the second seal ring structure and the connecting seal structure is composed of a first to (N−1)-th metal wire patterns vertically arranged and vias connecting vertically adjacent wire patterns, and the third seal ring structure is composed on an N-th wire pattern. In one or more of the foregoing and following embodiments, the semiconductor device further includes a pad electrode composed of a wiring pattern in the N-th wiring layer. In one or more of the foregoing and following embodiments, the N-th wiring layer is an uppermost wiring layer of the semiconductor device. In one or more of the foregoing and following embodiments, the semiconductor device further includes a connection pattern connecting a circuit in the first circuit area and a circuit in the second circuit area and bridging over the internal scribe line. In one or more of the foregoing and following embodiments, the connection pattern is composed of a wiring pattern in an uppermost wiring layer of the semiconductor device. In one or more of the foregoing and following embodiments, no functional circuit is disposed in the internal scribe line.

In accordance with another aspect of the present disclosure, a semiconductor device includes a circuit area disposed over a substrate, a first seal ring structure enclosing the circuit area, and a second seal ring structure disposed over the first seal ring structure and enclosing the circuit area. The first seal ring structure includes two lateral protrusions laterally protruding beyond the second seal ring structure in plan view. In one or more of the foregoing and following embodiments, the first seal ring structure is composed of wiring patterns in a first to an (N−M)-th wiring layers vertically arranged and vias connecting vertically adjacent wiring patterns, and the second seal ring structure is composed on wiring patterns in an (N−M+1)-th to an N-th wiring layers vertically arranged and vias connecting vertically adjacent wiring patterns, where M<N. In one or more of the foregoing and following embodiments, the semiconductor device further includes a pad electrode composed of a wiring pattern in the N-th wiring layer. In one or more of the foregoing and following embodiments, the N-th wiring layer is an uppermost wiring layer of the semiconductor device. In one or more of the foregoing and following embodiments, M is 1, 2 or 3.

In accordance with another aspect of the present disclosure, in a method of manufacturing a semiconductor device, a wafer including a plurality of chip areas is prepared. Each of the plurality of chip areas includes a first circuit area disposed over a substrate and enclosed by a first seal ring structure, a second circuit area disposed over the substrate and enclosed by a second seal ring structure, an internal scribe line disposed between the first circuit area and the second circuit area, and connecting seal structures connecting the first seal ring structure and the second seal ring structures such that a part of the first seal ring structure, a part of the second seal ring structure and the connecting seal structures enclose the internal scribe line. A third seal ring structure enclosing the first circuit area is formed over the first seal ring structure. The first circuit area and the second circuit area are separated by dicing the internal scribe line. In one or more of the foregoing and following embodiments, a fourth seal ring structure enclosing the second circuit area is formed over the second seal ring structure. In one or more of the foregoing and following embodiments, each of the first seal ring structure, the second seal ring structure and the connecting seal structure is composed of a first to an (N−M)-th metal wire patterns vertically arranged and vias connecting vertically adjacent wire patterns, and the third seal ring structure is composed on an N-th wire pattern in an uppermost wiring layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first circuit area disposed over a substrate and enclosed by a first seal ring structure;
a second circuit area disposed over the substrate and enclosed by a second seal ring structure;
an internal scribe line disposed between the first circuit area and the second circuit area; and
connecting seal structures connecting the first seal ring structure and the second seal ring structures such that a part of the first seal ring structure, a part of the second seal ring structure and the connecting seal structures enclose the internal scribe line.

2. The semiconductor device of claim 1, further comprising a third seal ring structure enclosing the first circuit area and the second circuit area.

3. The semiconductor device of claim 2, wherein:
each of the first seal ring structure, the second seal ring structure and the connecting seal structure is composed of wiring patterns in a first to (N−M)-th wiring layers vertically arranged relative to a main surface of the substrate and vias connecting vertically adjacent wiring patterns, and
the third seal ring structure is composed on wiring patterns in a (N−M+1)-th to an N-th wiring layers vertically arranged and vias connecting vertically adjacent wiring patterns, where M<N.

4. The semiconductor device of claim 3, further comprising a pad electrode composed of a wiring pattern in the N-th wiring layer.

5. The semiconductor device of claim 3, wherein the N-th wiring layer is an uppermost wiring layer of the semiconductor device.

6. The semiconductor device of claim 3, wherein M is 2 or 3.

7. The semiconductor device of claim 2, wherein:
each of the first seal ring structure, the second seal ring structure and the connecting seal structure is composed of a first to (N−1)-th metal wire patterns vertically arranged and vias connecting vertically adjacent wire patterns, and
the third seal ring structure is composed on an N-th wire pattern.

8. The semiconductor device of claim 7, further comprising a pad electrode composed of a wiring pattern in the N-th wiring layer.

9. The semiconductor device of claim 7, wherein the N-th wiring layer is an uppermost wiring layer of the semiconductor device.

10. The semiconductor device of claim 2, further includes a connection pattern connecting a circuit in the first circuit area and a circuit in the second circuit area and bridging over the internal scribe line.

11. The semiconductor device of claim 10, wherein the connection pattern is composed of a wiring pattern in an uppermost wiring layer of the semiconductor device.

12. The semiconductor device of claim 2, wherein no functional circuit is disposed in the internal scribe line.

13. A semiconductor device, comprising:
a circuit area disposed over a substrate;
a first seal ring structure enclosing the circuit area; and
a second seal ring structure disposed over the first seal ring structure and enclosing the circuit area,
wherein the first seal ring structure includes two lateral protrusions laterally protruding beyond the second seal ring structure in plan view.

14. The semiconductor device of claim 13, wherein:
the first seal ring structure is composed of wiring patterns in a first to an (N−M)-th wiring layers vertically arranged and vias connecting vertically adjacent wiring patterns, and
the second seal ring structure is composed on wiring patterns in an (N−M+1)-th to an N-th wiring layers vertically arranged relative to a main surface of the substrate and vias connecting vertically adjacent wiring patterns, where M<N.

15. The semiconductor device of claim 14, further comprising a pad electrode composed of a wiring pattern in the N-th wiring layer.

16. The semiconductor device of claim 14, wherein the N-th wiring layer is an uppermost wiring layer of the semiconductor device.

17. The semiconductor device of claim 14, wherein M is 1, 2 or 3.

18. A method of manufacturing a semiconductor device, the method comprising:
preparing a wafer including a plurality of chip areas, each of the plurality of chip areas including:
a first circuit area disposed over a substrate and enclosed by a first seal ring structure;
a second circuit area disposed over the substrate and enclosed by a second seal ring structure;
an internal scribe line disposed between the first circuit area and the second circuit area; and
connecting seal structures connecting the first seal ring structure and the second seal ring structures such that a part of the first seal ring structure, a part of the second seal ring structure and the connecting seal structures enclose the internal scribe line;
forming a third seal ring structure enclosing the first circuit area over the first seal ring structure; and
separating the first circuit area and the second circuit area by dicing the internal scribe line.

19. The method of claim 18, further comprising forming a fourth seal ring structure enclosing the second circuit area over the second seal ring structure.

20. The method of claim 18, wherein:
each of the first seal ring structure, the second seal ring structure and the connecting seal structure is composed of a first to an (N−M)-th metal wire patterns vertically arranged relative to a main surface of the wafer and vias connecting vertically adjacent wire patterns, and
the third seal ring structure is composed on an N-th wire pattern in an uppermost wiring layer.
